(19) United States
(12) Patent Application Publication
(10) Pub. No.: US 2014/0078700 A1
(43) Pub. Date: Mar. 20, 2014

(54) CIRCUIT BOARD DEVICE AND ELECTRONIC DEVICE

(71) Applicant: FUJITSU LIMITED, Kawasaki-shi (JP)

(72) Inventors: Takumi MASUYAMA, Kawasaki (JP); Satoshi EMOTO, Nagano (JP); Toru OKADA, Yokohama (JP); Hiroshi KOBAYASHI, Kawasaki (JP)

(73) Assignee: FUJITSU LIMITED, Kawasaki-shi (JP)

(21) Appl. No.: 13/960,882

(22) Filed: Aug. 7, 2013

(30) Foreign Application Priority Data
Sep. 20, 2012 (JP) 2012-207341

(51) Int. Cl. H05K 1/02

(52) U.S. Cl. CPC H05K 1/0271
USPC 361/760

(57) ABSTRACT

A circuit board device includes: a circuit board; an electronic component bonded to a first surface of the circuit board via an electronic component-bonding portion that is disposed over a rectangular region; and a reinforcing member disposed at one of four corners of a rectangular region of a second surface of the circuit board that is at a position corresponding to a position of the rectangular region of the first surface on a side opposite a side on which the rectangular region is present, wherein the reinforcing member includes a stress receiving portion having an outer edge located in a diagonal line direction of the rectangular region of the second surface and a stress dispersing portion extending in such a manner as to have a fan-like shape or a substantially fan-like shape toward the inside in the diagonal line direction with the stress receiving portion.

### CROSS-REFERENCE TO RELATED APPLICATION

This application is based upon and claims the benefit of priority of the prior Japanese Patent Application No. 2012-207341, filed on Sep. 20, 2012, the entire contents of which are incorporated herein by reference.

### FIELD

The embodiments discussed herein are related to a circuit board device that includes a reinforcing member and an electronic device that includes a reinforcing member.

### BACKGROUND

A circuit board on which an electronic component such as a semiconductor unit is mounted is often incorporated in an electronic device. In recent years, electronic devices have been reduced in size, and circuit boards that are to be incorporated in such electronic devices have been reduced in size due to high-density mounting. Electronic components such as semiconductor units that are to be mounted on such circuit boards have been also reduced in size.

Along with the above size reduction, a mounting structure for mounting an electronic component on a circuit board has also become smaller. A solder bump is often used as a bond member that is used to mount a semiconductor unit on a circuit board. A semiconductor may be electrically connected and mechanically fixed to a circuit board by solder bonding using a solder bump.

When a mounting structure is small as described above, and a solder bump is small, a solder-bonding portion is also small. Thus, deformation easily occurs in a solder bump-bonding portion, and the solder bump-bonding portion is easily damaged due to thermal stress or external pressure. As a result, a poor connection is likely to occur.

Consequently, as illustrated in FIG. 27, a method of reinforcing bonding bumps 41 that are solder bumps by filling an area between a circuit board 10, on which a semiconductor unit 21 and passive elements 22 are mounted, and the semiconductor unit 21 with an underfill material 42 has been employed.

In other words, a method of reinforcing the bonding bumps 41 by filling areas in the periphery of the bonding bumps 41 with the underfill material 42, which is made of an epoxy resin or the like, and of mechanically fixing the semiconductor unit 21 to the circuit board 10 by bonding the bottom surface of the semiconductor unit 21 and a surface of the circuit board 10 together using the underfill material 42 has been employed. With this method, influences from thermal stress and external force may be reduced, and pressure resistance and long-term reliability of the bonding bumps 41 may be improved.

A method of making a circuit board resistant to deformation by reinforcing the circuit board has been proposed, and also with such reinforcement, pressure resistance and long-term reliability of a mounting structure for a solder bonding portion or the like may be improved. As such a reinforcing method, a method of dispersing stress propagated to a portion of a circuit board on which a semiconductor unit is mounted by bonding a reinforcing member to the bottom surface of the circuit board by solder bonding without using an underfill material has been proposed.

When stress propagated to a portion of a circuit board on which a semiconductor unit is mounted is dispersed by a reinforcing member, pressure resistance and long-term reliability of an electronic component-bonding portion may be improved.

However, when the footprint of a reinforcing member is large, the reinforcing member takes up a large amount of space as a component in a circuit board device that has been reduced in size or in an electronic device that includes such a circuit board device.

The followings are reference documents:
[Document 1] Japanese Laid-open Patent Publication No. 2011-258836,
[Document 2] Japanese Laid-open Patent Publication No. 2007-12695,
[Document 3] Japanese Laid-open Patent Publication No. 2010-93310,
[Document 4] Japanese Laid-open Patent Publication No. 2006-210852,
[Document 5] Japanese Laid-open Patent Publication No. 2003-283081,
[Document 6] Japanese Laid-open Patent Publication No. 2001-244585,
[Document 7] Japanese Laid-open Patent Publication No. 2003-332496, and
[Document 8] Japanese Laid-open Patent Publication No. 2010-21286.

### SUMMARY

According to an aspect of the invention, a circuit board device includes: a circuit board; an electronic component bonded to a first surface of the circuit board via an electronic component-bonding portion that is disposed over a rectangular region; and a reinforcing member disposed at one of four corners of a rectangular region of a second surface of the circuit board that is at a position corresponding to the position of the rectangular region of the first surface on a side opposite the side on which the rectangular region is present, wherein the reinforcing member includes a stress receiving portion having an outer edge located along a diagonal axis of the rectangular region of the second surface that is positioned outside the corner of the rectangular region along the diagonal axis and a stress dispersing portion extending so as to have a fan-like shape or a substantially fan-like shape toward the center of the diagonal axis with the stress receiving portion being an end of the fan-like shape or the substantially fan-like shape.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a side view of a circuit board device according to a first embodiment;

FIG. 2 is a bottom view of the circuit board device according to the first embodiment;

FIG. 3 is a first explanatory diagram illustrating a reinforcing member according to the first embodiment;

FIG. 4 is a second explanatory diagram illustrating the reinforcing member according to the first embodiment;

FIG. 5 is a third explanatory diagram illustrating the reinforcing member according to the first embodiment;

FIG. 6 is an explanatory diagram illustrating a stress receiving portion according to the first embodiment;

FIG. 7 is an explanatory diagram illustrating a stress dispersing portion according to the first embodiment;

FIG. 8 illustrates simulation results indicating the relationship between covered bumps and maximum stress according to the first embodiment;

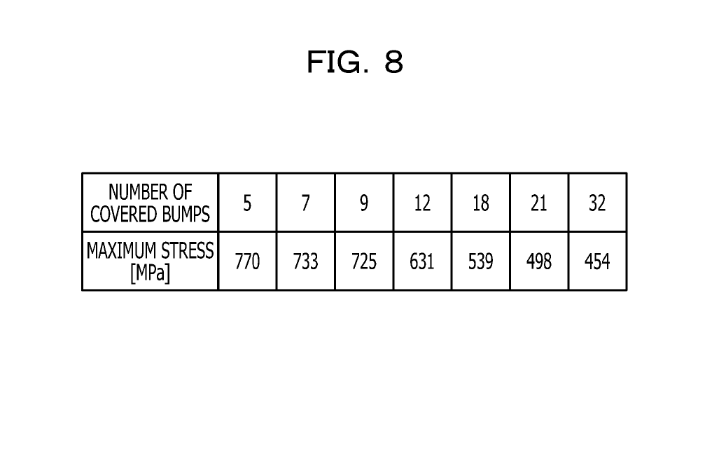

FIG. 9 illustrates simulation results indicating the relationship between maximum stress and the footprint of the reinforcing member according to the first embodiment;

FIG. 10 is a side view of a circuit board device according to a first comparative example;

FIG. 11A is a bottom view of a circuit board device according to a second comparative example;

FIG. 11B is an explanatory diagram illustrating a reinforcing member according to the second comparative example;

FIG. 12 is a bottom view of a circuit board device according to a third comparative example;

FIG. 13 is a bottom view of a circuit board device according to a fourth comparative example;

FIG. 14 is a bottom view of a circuit board device according to a fifth comparative example;

FIG. 15 is a bottom view of a circuit board device according to a sixth comparative example;

FIG. 16 is a bottom view of a circuit board device according to a seventh comparative example;

FIG. 17 is a bottom view of a circuit board device according to a modification of the first embodiment;

FIG. 18 is an explanatory diagram illustrating a reinforcing member according to the modification of the first embodiment;

FIG. 19 is a perspective view of an electronic device according to the first embodiment;

FIG. 20 is an explanatory diagram illustrating a reinforcing member according to a second embodiment;

FIG. 21A is a first explanatory diagram illustrating stress generated in a bonding bump according to the second embodiment;

FIG. 21B is a second explanatory diagram illustrating the stress generated in the bonding bump according to the second embodiment;

FIG. 21C is a third explanatory diagram illustrating the stress generated in the bonding bump according to the second embodiment;

FIG. 22A is a first explanatory diagram illustrating a stress generated in a bonding bump according to the first embodiment;

FIG. 22B is a second explanatory diagram illustrating the stress generated in the bonding bump according to the first embodiment;

FIG. 22C is a third explanatory diagram illustrating the stress generated in the bonding bump according to the first embodiment;

FIG. 23 is an explanatory diagram illustrating a reinforcing member according to a first modification of the second embodiment;

FIG. 24 illustrates simulation results indicating maximum stress according to the second embodiment;

FIG. 25 is a sectional view of a reinforcing member according to a second modification of the second embodiment;

FIG. 26 illustrates simulation results indicating maximum stress according to the second modification of the second embodiment; and

FIG. 27 is a side view of a circuit board device according to the related art.

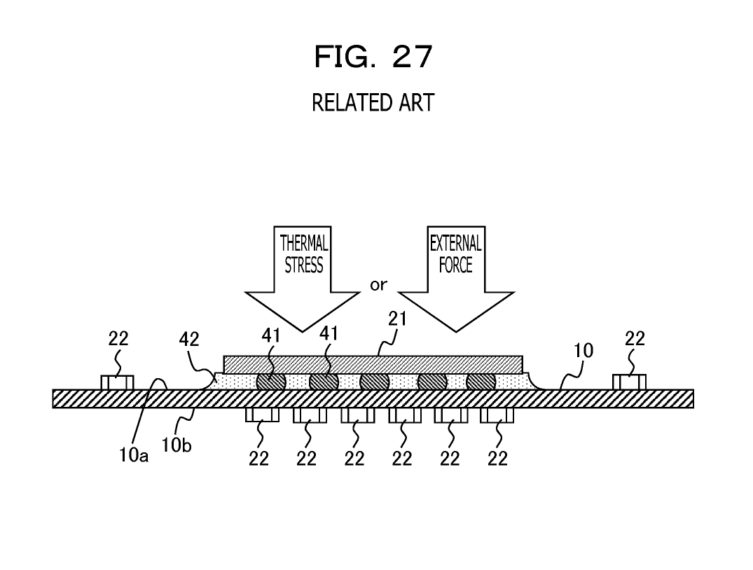

### DESCRIPTION OF EMBODIMENTS

A circuit board device and an electronic device according to first and second embodiments will now be described below with reference to the drawings.

### First Embodiment

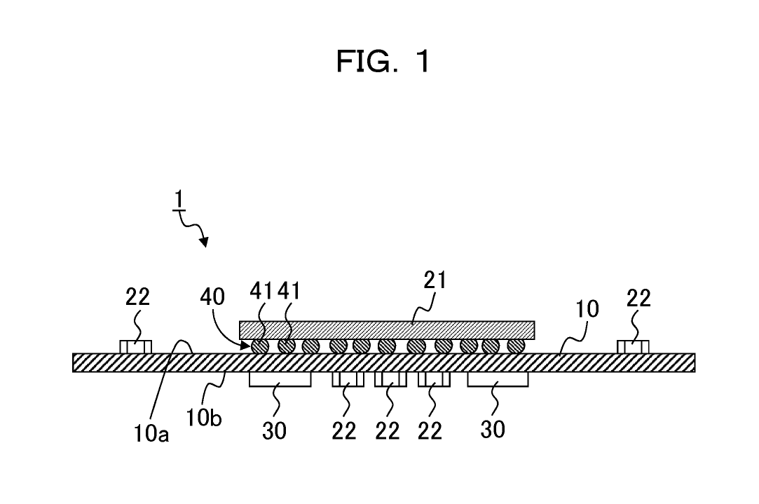

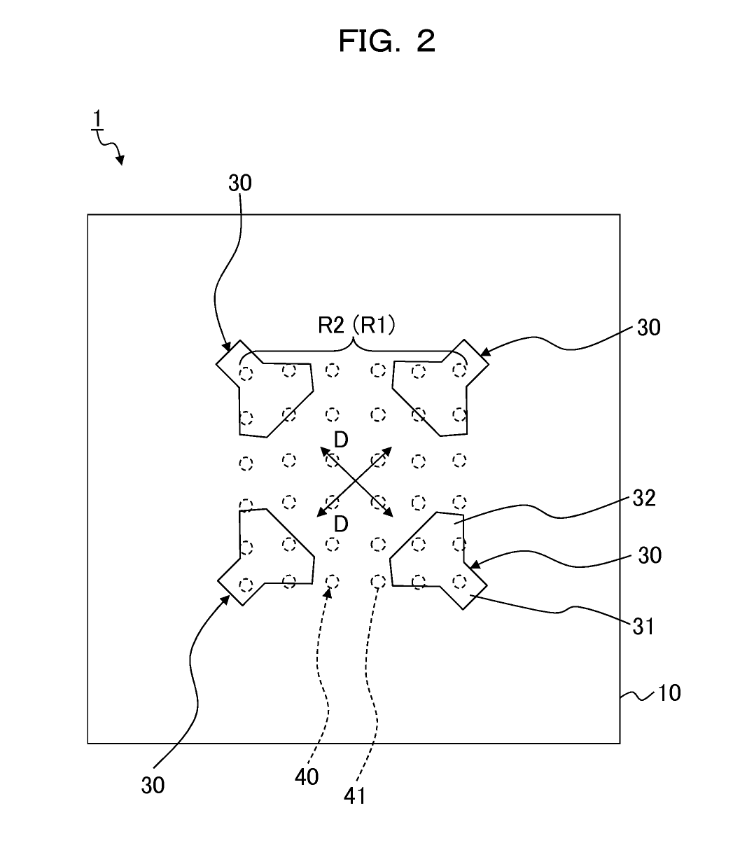

FIGS. 1 and 2 are a side view and a bottom view, respectively, of a circuit board device 1 according to the first embodiment.

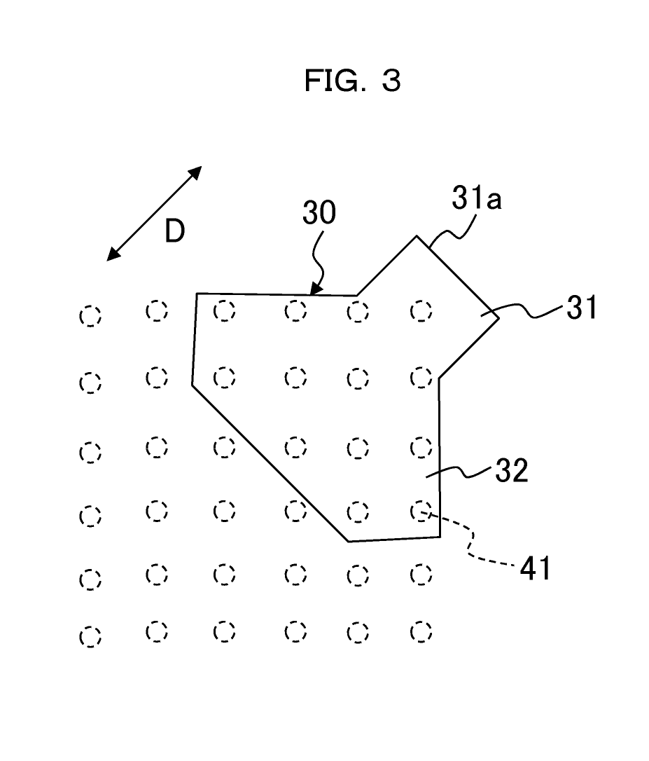

FIGS. 3 to 5 are explanatory diagrams illustrating a reinforcing member 30 according to the first embodiment.

The circuit board device 1 includes a circuit board 10, a reinforcing member 30, and a semiconductor unit 21, which is an example of an electronic component.

The semiconductor unit 21 is, for example, a so-called ball grid array (BGA) semiconductor package. An electronic component-bonding portion 40 includes a plurality of bonding bumps 41, and examples of the plurality of bonding bumps 41 are solder bumps. The semiconductor unit 21 is bonded (for example, by flip chip packaging) to a first surface 10a of the circuit board 10 via the bonding bumps 41 that are disposed over a rectangular region R1 illustrated in FIG. 2.

An example of the circuit board 10 is a substrate made of a glass epoxy resin or the like on which a circuit and a connecting electrode are formed from a copper pattern. With the circuit board 10, components such as a plurality of passive elements 22, including capacitors and resistance elements, are mounted on the first surface 10a and a second surface 10b opposite the first surface 10a.

The reinforcing member 30 is disposed at one of four corners of a rectangular region R2 of the second surface 10b. The rectangular region R2 is at a position corresponding to the position of the rectangular region R1 of the first surface 10a of the circuit board 10 on a side opposite to a side on which the rectangular region R1 is present. Although it is sufficient to dispose only one reinforcing member 30, preferably two or three reinforcing members 30 may be disposed, which includes disposing two reinforcing members 30 to face each other along one of diagonal axes D. More preferably, a total of four reinforcing members 30 may be disposed with one reinforcing member 30 at each of the four corners of the rectangular region R2.

As illustrated in FIGS. 2 to 5, the reinforcing member 30 includes a stress receiving portion 31 and a stress dispersing portion 32. The material that makes up the reinforcing member 30 is not particularly limited because the reinforcing member 30 may considerably reinforce the circuit board 10 even if the reinforcing member 30 is made of any material. However, it is preferable that the reinforcing member 30 be a plate-shaped member made of, for example, a metal or a ceramic material having strength higher than that of the material of the circuit board 10. The reinforcing member 30 is to be attached to the circuit board 10 using, for example, a resin adhesive. However, a copper pattern may be formed on the circuit board 10, and the reinforcing member 30 may be bonded to the circuit board 10 using a bond member such as solder.

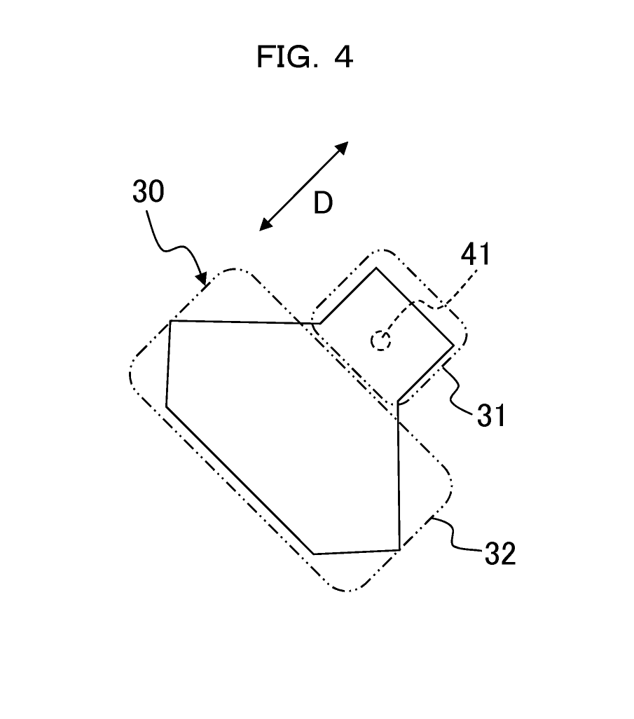

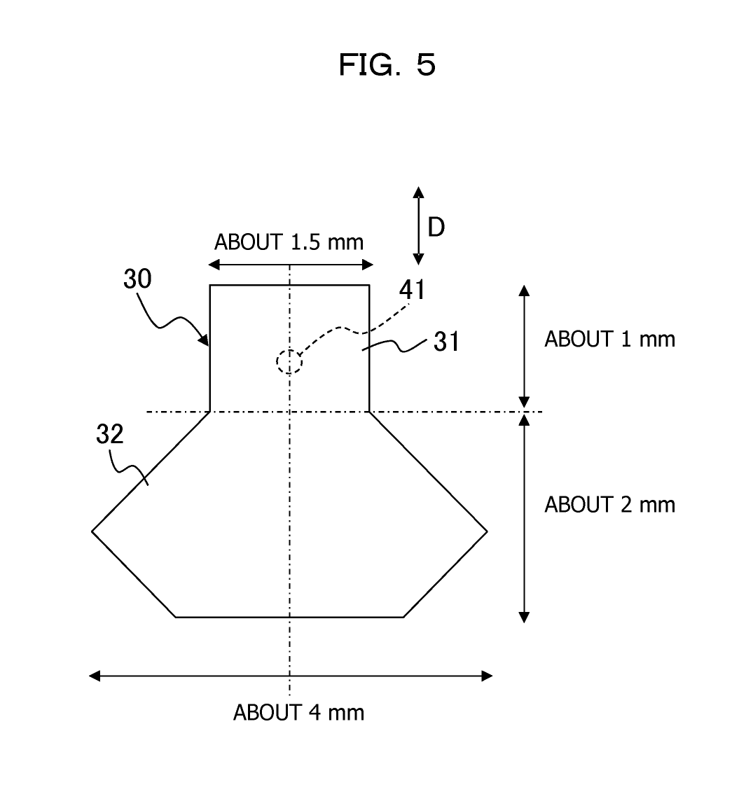

An outer edge 31a of the stress receiving portion 31 located in a corresponding one of the diagonal axes D of the rectangular region R2 in the second surface 10b of the circuit board 10 (a direction away from the center of the rectangular region R2) is positioned outside a corresponding one of the corners of the rectangular region R2 along the diagonal axis D. The stress receiving portion 31 has a shape that covers the bonding bump 41 at the corner of the rectangular region R2 (the bonding bump 41 illustrated in FIGS. 4 and 5).

The stress receiving portion 31 has a square shape extending over an area inside and an area outside the corner of the rectangular region R2 of the second surface 10b along the diagonal axis D. As illustrated in FIG. 3, the outer edge 31a of the stress receiving portion 31 located along the diagonal axis D is a side substantially perpendicular to the diagonal axis D.

The stress dispersing portion 32 extends so as to have a substantially fan-like shape toward the inside of the rectangular region R2 along the diagonal axis D with the stress receiving portion 31 being the top of the substantially fan-like shape. Examples of the substantially fan-like shape include a shape having an arc portion in the form of a fan that includes three straight lines as illustrated in FIGS. 2 to 5 or includes four or more straight lines, a shape having an arc portion in the form of a fan that includes a curved line instead of one or more of such straight lines, a shape having an arc portion in the form of a fan that includes a plurality of curved lines each having a different center of curvature, and the like. The stress dispersing portion 32 may be disposed at a position corresponding to positions of at least one or more of the bonding bumps 41 on a side opposite the side on which the bonding bumps 41 are disposed.

By way of example, dimensions of the reinforcing member 30 as illustrated in FIG. 5 will be described. The length of the stress receiving portion 31 along the diagonal axis D is about 1 mm, and the length of the stress dispersing portion 32 along the diagonal axis D is about 2 mm. The length of the stress receiving portion 31 along an axis substantially perpendicular to the diagonal axis D is about 1.5 mm, and the length of the stress dispersing portion 32 along an axis substantially perpendicular to the diagonal axis D is about 4 mm. The dimensions of the rectangular regions R1 and R2 illustrated in FIG. 2 are, for example, 25 to 30 mm×25 to 30 mm. The dimensions of the reinforcing member 30 and the rectangular regions R1 and R2 are merely examples, and the reinforcing member 30 and the rectangular regions R1 and R2 may become larger or smaller depending on the circuit board device 1 and an electronic device 100 which will be described later.

When the reinforcing member 30 is not arranged on the second surface 10b, an external force that is applied to an area outside a mounting region of the circuit board 10 (for example, the rectangular region R1 of the first surface 10a) is propagated within the circuit board 10 to the mounting region as stress. The stress propagated to the mounting region is concentrated at four corners of the quadrilateral semiconductor unit 21, and as a result, the stress is concentrated at the bonding bumps 41 closest to the four corners.

Therefore, as described above, a total of four reinforcing members 30 may be positioned at each of the four corners of the rectangular region R2, and the outer edge 31a of each of the stress receiving portions 31 located along the corresponding diagonal axis D may be positioned outside the corresponding corner of the rectangular region R2 along the diagonal axis D. In addition, as described above, the outer edge 31a of each of the stress receiving portions 31 located along the corresponding diagonal axis D may be a side extending in a direction perpendicular to the diagonal axis D.

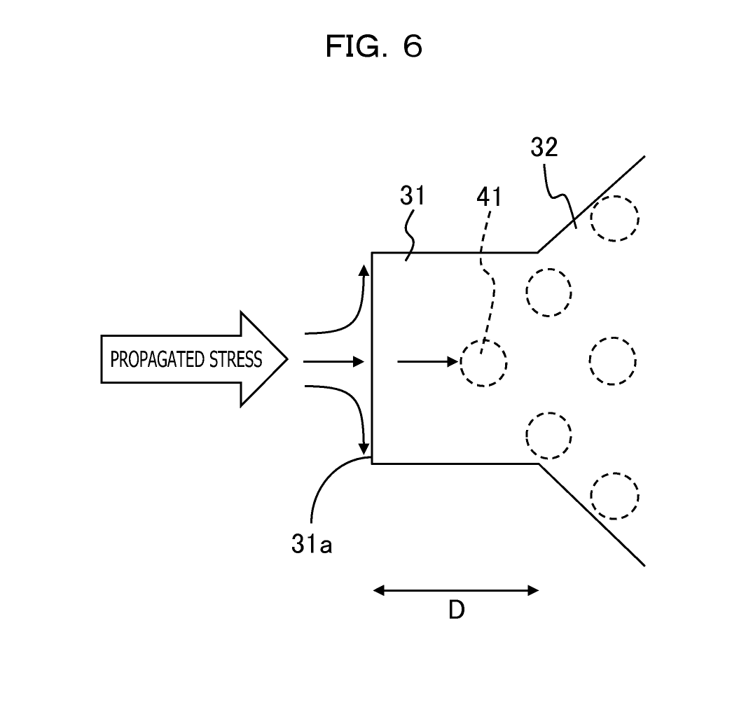

As illustrated in FIG. 6, the stress receiving portion 31 reinforces the circuit board 10 as a rigid body and receives propagated stress before the bonding bump 41 at the corner does, and thus, the stress receiving portion 31 has an advantageous effect of reducing stress that would have been concentrated at the bonding bump 41.

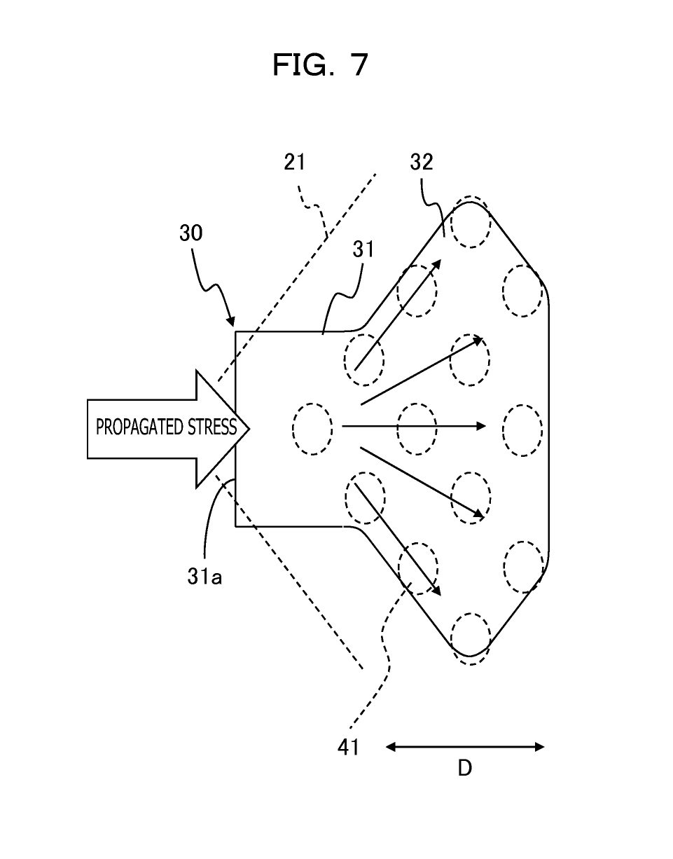

As illustrated in FIG. 7, the stress dispersing portion 32 is positioned further inside than the bonding bump 41 at the corner of the semiconductor unit 21 that is represented by hidden lines (dashed lines) and that is not illustrated in FIG. 6 in the diagonal axis D. The stress dispersing portion 32 is disposed so as to cover at least one or more of the bonding bumps 41 different from the bonding bump 41 at the corner, and reinforces the circuit board 10.

The stress dispersing portion 32 holds the circuit board 10 from the second surface 10b, which is the bottom surface of the circuit board 10m by being bonded to the second surface 10b by solder bonding or the like. Thus, a portion of the circuit board 10 at which the stress dispersing portion 32 is positioned may be considered as a rigid body. Stress that would have been concentrated at the bonding bump 41 at a corner is propagated to the bonding bumps 41 in a region that is covered with the stress dispersing portion 32, by being received by an overall rigid area.

As a result, propagated stress may be reduced by being dispersed into each of the bonding bumps 41. As the number of the bonding bumps 41 that are covered by the stress dispersing portion 32 becomes larger, an area that may be considered as a rigid body becomes larger, and thus, the dispersing effect on the stress improves.

Here, the dispersing effect of the stress dispersing portion 32 on a stress (the von Mises stress, which is the maximum stress) according to the number of the bonding bumps 41 covered with the stress dispersing portion 32 is verified by simulation.

The reinforcing members 30 are positioned at bump positions of four corners of a BGA (the semiconductor unit 21) by using Sn—Ag—Cu (SAC) solder. The model shape of each element is configured to imitate a mobile device. The circuit board 10 is an FR-4 (flame retardant type 4: a glass epoxy board). The length of one side of the circuit board 10 is 110 mm, and the thickness t of the circuit board 10 is 1.0 mm. The length of one side of the BGA is 30 mm, and the thickness t of the BGA is 0.8 mm. Each of the bonding bumps 41 has a diameter of 0.4 mm, and the pitch of the bonding bumps 41 is 0.8 mm. The value given here are approximate.

Evaluations are performed using a model in which the four corners of the circuit board 10 are completely fixed in place, and in which the center of the BGA is pressed with a force of 42 N from a side on which the BGA is present, and the maximum stress applied to the bonding bumps 41 is measured. When a force of 42 N is applied to the model that is used in this case, a standard is satisfied when the stress at a maximum stress portion is 700 MPa or lower.

Results of the evaluations are as follows:
when the number of covered bumps is 5, the maximum stress is 770 MPa,
when the number of the covered bumps is 7, the maximum stress is 733 MPa,
when the number of the covered bumps is 9, the maximum stress is 725 MPa,
when the number of the covered bumps is 12, the maximum stress is 631 MPa,
when the number of the covered bumps is 18, the maximum stress is 539 MPa,
when the number of the covered bumps is 21, the maximum stress is 498 MPa, and
when the number of the covered bumps is 32, the maximum stress is 454 MPa.

As described above, it is seen that as the number of the covered bumps becomes larger, the dispersing effect on a stress becomes larger. In the examples of the simulation, it may be said that a shape with which the stress dispersing portion 32 covers 12 to 18 bonding bumps 41 is a shape compatible with both reducing the size of the reinforcing member 30 and maintaining pressure resistance and long-term reliability of the reinforcing member 30.

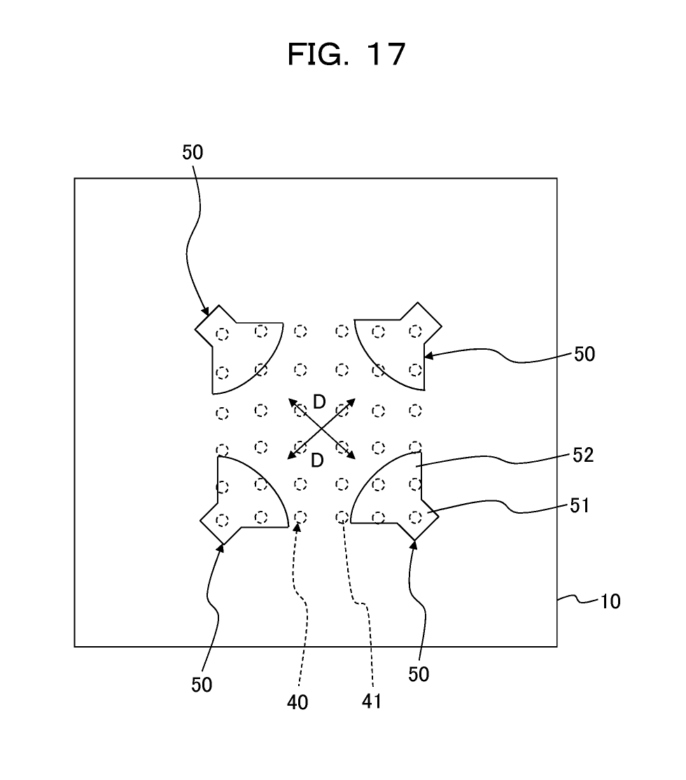

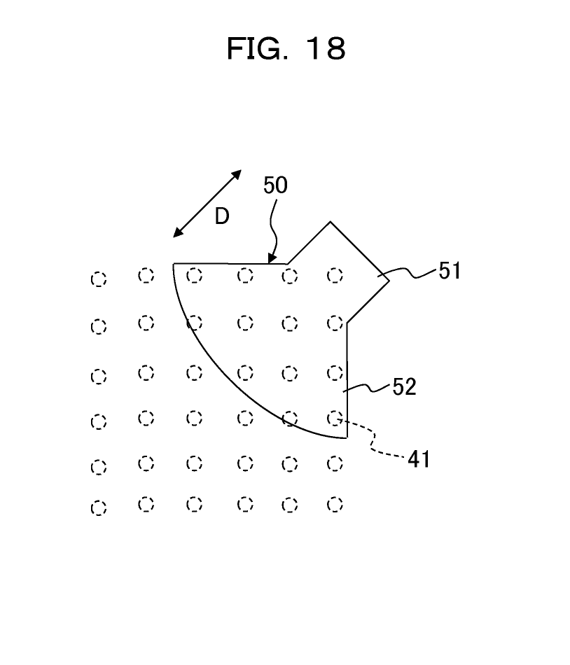

In the first embodiment, as illustrated in FIGS. 2 to 5, the stress dispersing portion 32 extends so as to have a substantially fan-like shape. However, the stress dispersing portion 32 may extend like a stress dispersing portion 52 of a reinforcing member 50 illustrated in FIGS. 17 and 18 that extends so as to have a fan-like shape having an arc portion that faces toward the center of a corresponding one of the diagonal axes D, with a stress receiving portion 51 being the end of the fan-like shape.

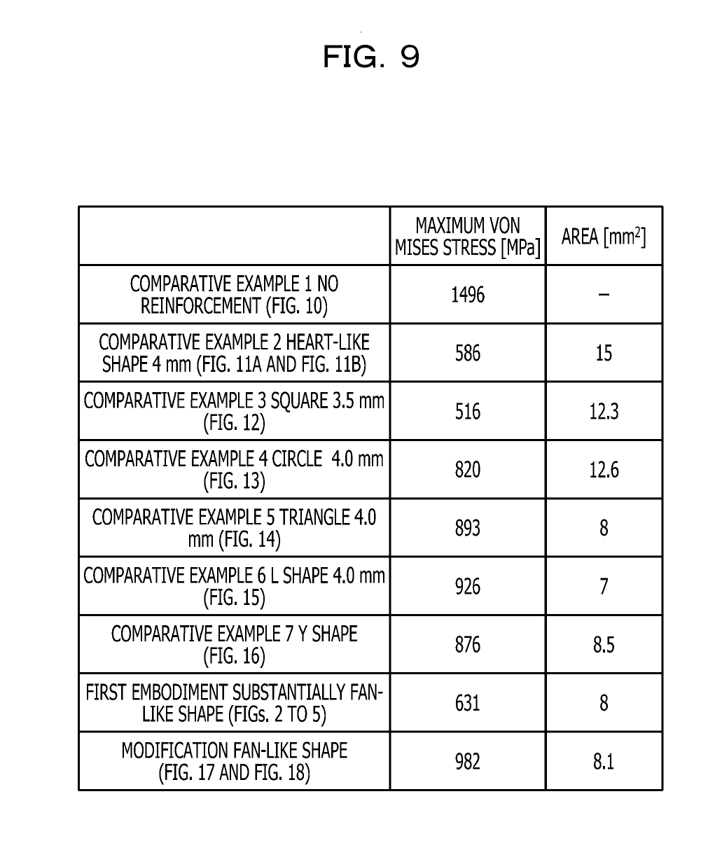

Here, a structure analysis simulation is performed in order to perform comparisons and verifications with respect to the footprint of reinforcing members and the dispersing effect on a stress in comparative examples. When the stress at a maximum stress portion (for example, the bonding bump 41 at a corner) is 700 MPa or lower, a standard is satisfied. The comparisons are performed using the reinforcing members according to the comparative examples each having a shape one side of which is within a range of 4 mm or less in length. FIG. 9 illustrates the results, and the comparative examples and the first embodiment will be described below.

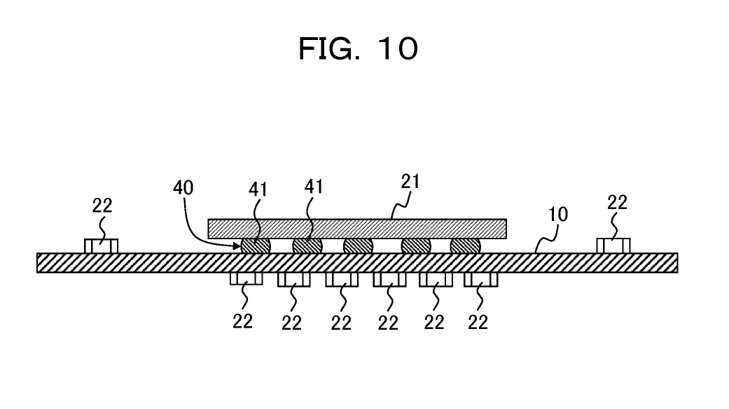

First, a first comparative example is where a reinforcing member is not arranged on a side opposite a side on which the electronic component-bonding portion 40 is formed with the circuit board 10 interposed therebetween as illustrated in FIG. 10. In this case, although there is no footprint of a reinforcing member, the maximum stress is 1,496 MPa, and the standard is not satisfied.

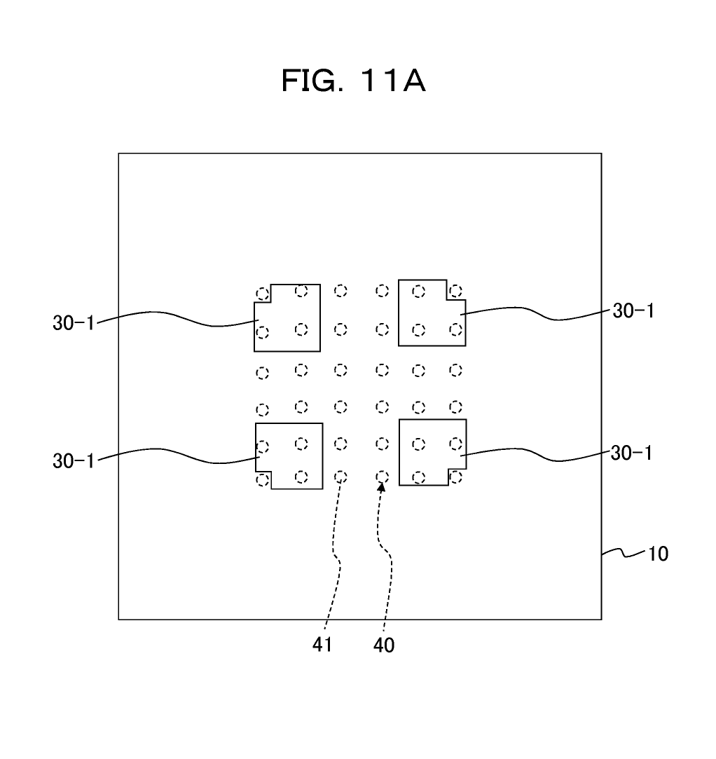

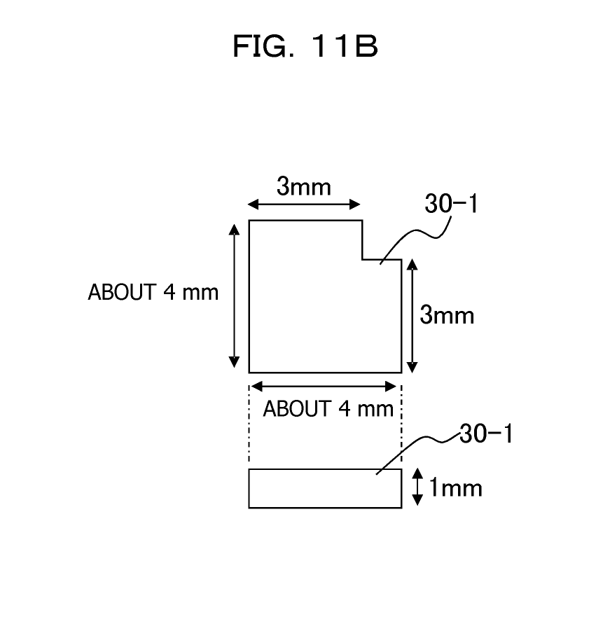

Next, heart-shaped reinforcing members 30-1 according to a second comparative example each have, as illustrated in FIGS. 11A and 11B, a square shape having a cutout portion facing away from the center of a corresponding one of diagonal axes D of the electronic component-bonding portion 40 at a position corresponding to the bonding bump 41 at a corresponding one of corners of the electronic component-bonding portion 40. Regarding the dimensions of each of the reinforcing members 30-1, as illustrated in FIG. 11B, the length of one side is about 4 mm, and the length of one side without the cutout portion is about 3 mm. The thickness of each of the reinforcing members 30-1 is 1 mm and is similar to those of the reinforcing members according to the other comparative examples. In second comparative example, the maximum stress is 586 MPa, and the standard is satisfied. However, the footprint of each of the reinforcing members 30-1 is 15 mm², which is comparatively large.

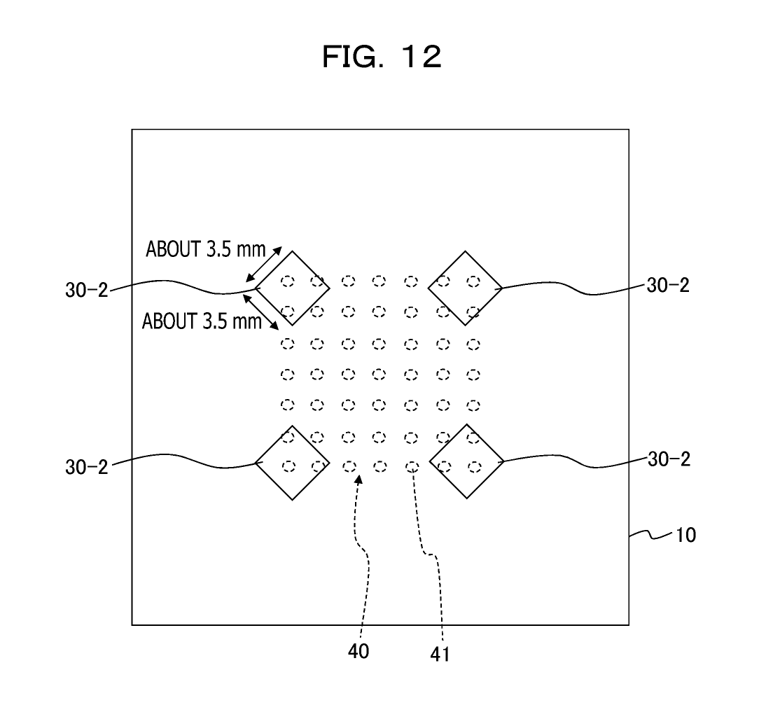

Next, square reinforcing members 30-2 according to a third comparative example each have, as illustrated in FIG. 12, a square shape having sides extending in a direction parallel to a corresponding one of diagonal axes of the electronic component-bonding portion 40 and sides extending in a direction perpendicular to the diagonal axis. Regarding the dimensions of each of the reinforcing members 30-2, the length of one side is about 3.5 mm. In the third comparative example, the maximum stress is 515 MPa, and the standard is satisfied. However, the footprint of each of the reinforcing members 30-2 is 12.3 mm², which is comparatively large.

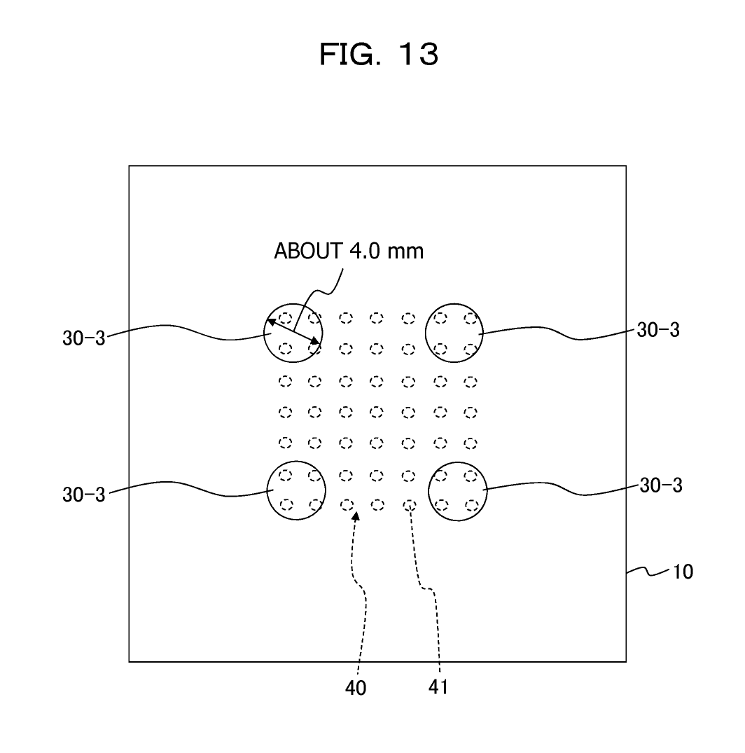

Next, circular reinforcing members 30-3 according to a fourth comparative example each have, as illustrated in FIG. 13, a circle shape having a diameter of about 4.0 mm. In fourth comparative example, the maximum stress is 820 MPa, and the standard is not satisfied. In addition, the footprint of each of the reinforcing members 30-3 is 12.6 mm², which is comparatively large.

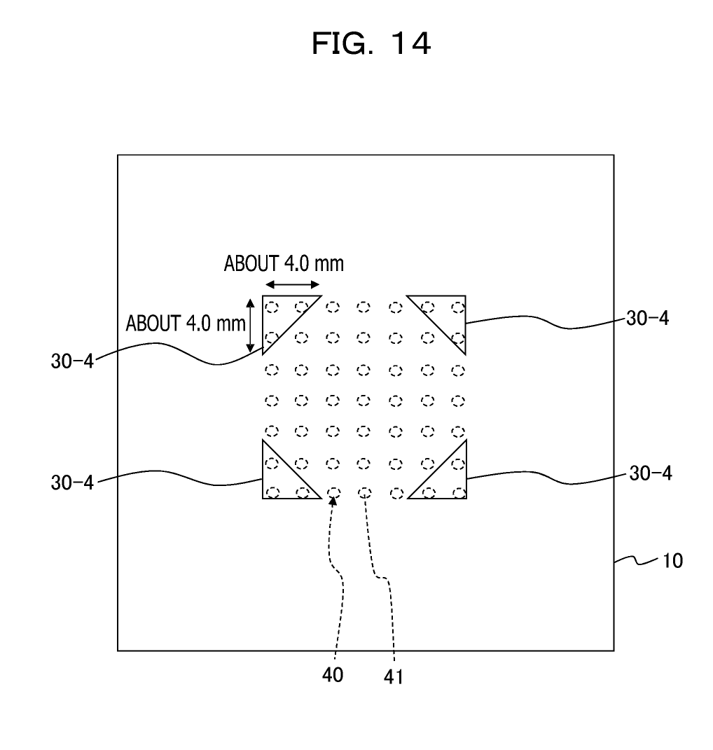

Next, triangular reinforcing members 30-4 according to fifth comparative example each have, as illustrated in FIG. 14, an isosceles triangle shape, and in the isosceles triangle shape, two sides that are parallel to two sides of the electronic component bonding portion 40 perpendicular to each other have the approximately same length. The approximate length of the two sides of each of the reinforcing members 30-4 are about 4.0 mm. In fifth comparative example, the footprint of each of the reinforcing members 30-4 is 8 mm², which is small. However, the maximum stress is 893 MPa, and the standard is not satisfied.

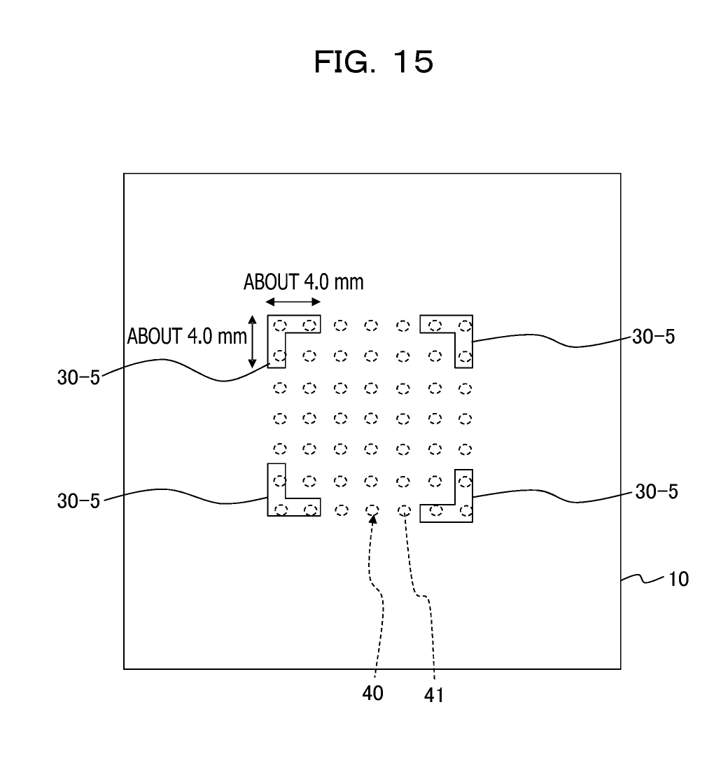

Next, L-shaped reinforcing members 30-5 according to a sixth comparative example each have, as illustrated in FIG. 15, an L shape that includes two portions each of which is parallel to a corresponding one of two sides of the electronic component bonding portion 40 perpendicular to each other. The dimension of each of the reinforcing members 30-5 is about 4.0 mm×about 4.0 mm. In the sixth comparative example, the footprint of each of the reinforcing members 30-5 is 7 mm², which is small. However, the maximum stress is 926 MPa, and the standard is not satisfied.

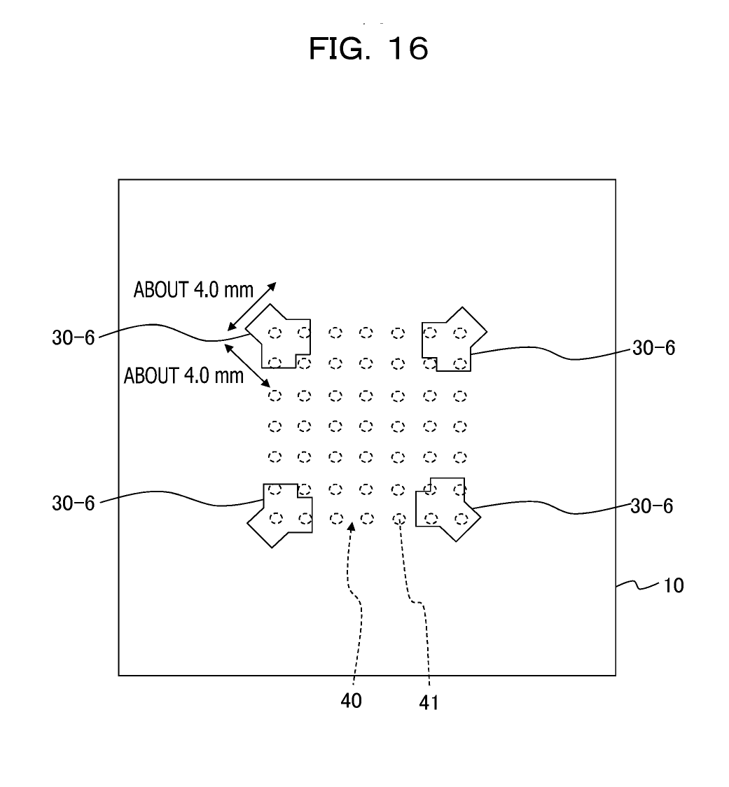

Next, Y-shaped reinforcing members 30-6 according to seventh comparative example each have, as illustrated in FIG. 16, a Y shape facing toward the center of the electronic component-bonding portion 40. The dimension of each of the reinforcing members 30-6 is about 4.0 mm×about 4.0 mm. In seventh comparative example, the footprint of each of the reinforcing members 30-6 is 8.5 mm², which is somewhat small. However, the maximum stress is 876 MPa, and the standard is not satisfied.

Next, in each of the reinforcing members 30 according to the first embodiment illustrated in FIGS. 2 to 5, the stress dispersing portion 32 extends so as to have a substantially fan-like shape as described above. The dimensions of each of the reinforcing members 30 are 4.0 mm×about 3.00 mm. More specifically, as described above, the length of the stress receiving portion 31 along the diagonal axis D is about 1 mm, and the length of the stress dispersing portion 32 along the diagonal axis D is about 2 mm as illustrated in FIG. 5. The length of the stress receiving portion 31 in a direction perpendicular to the diagonal axis D is about 1.5 mm, and the length of the stress dispersing portion 32 in a direction perpendicular to the diagonal axis D is about 4 mm. In the first embodiment, the footprint of each of the reinforcing members 30 is 8 mm², which is small. In addition, the maximum stress is 631 MPa, and the standard is satisfied.

Next, in each of the reinforcing members 50 according to a modification of the first embodiment illustrated in FIGS. 17 and 18, the stress dispersing portion 52 extends so as to have a fan-like shape as described above. The dimensions of each of the reinforcing members 50 are 4.0 mm×about 3.00 mm, which are similar to those of the reinforcing member 30. In the present modification, the footprint of each of the reinforcing members 50 is 8.1 mm², which is small. In addition, the maximum stress is 682 MPa, and the standard is satisfied.

As described above, it is seen that, in the first embodiment and the modification of the first embodiment, the shapes of the reinforcing member 30 and the reinforcing member 50 may be reduced in size while the maximum stress is reduced in such a manner that the standard is satisfied.

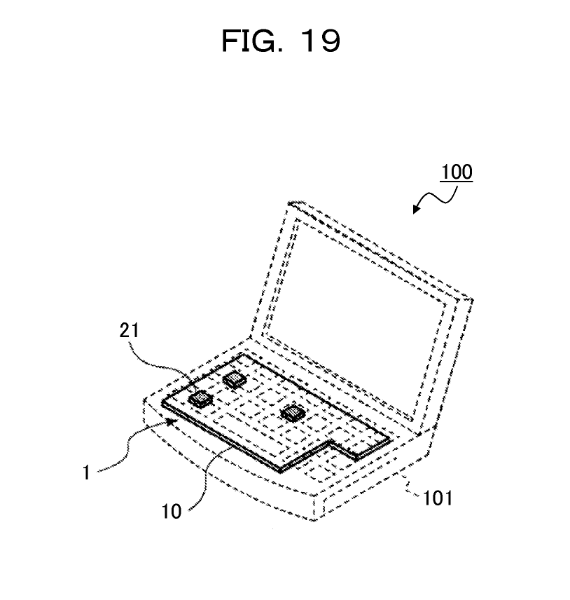

The circuit board device 1, which has been described above, is to be disposed in, for example, the electronic device 100 illustrated in FIG. 19. An example of the electronic device 100 is a laptop computer as illustrated in FIG. 19. The circuit board device 1 in which the semiconductor unit 21 is mounted on the circuit board 10 is disposed within a main body 101 of the electronic device 100.

When the electronic device 100 is a laptop computer as illustrated in FIG. 19, the electronic device 100 is thin, and a force applied to the main body 101 from the outside is likely to be propagated to the circuit board 10. As a result, deformation is likely to occur in the circuit board 10. Therefore, using the reinforcing member 30 according to the first embodiment enables stress propagated to the electronic component-bonding portion 40 between the semiconductor unit 21 and the circuit board 10 to be dispersed and enables improved pressure resistance and long-term reliability of the electronic component-bonding portion 40. The electronic device 100 is not limited to a laptop computer and may be another device as long as the electronic device 100 includes the circuit board device 1.

When the reinforcing member 30 according to the first embodiment is used, the semiconductor unit 21 may be arranged such that the semiconductor unit 21 is not fixed to the circuit board 10 with an underfill material, and when an underfill material is not used, the semiconductor unit 21 may be easily removed from the circuit board 10.

In the first embodiment, which has been described above, the reinforcing member 30 includes the stress receiving portion 31 and the stress dispersing portion 32. The outer edge 31a of the stress receiving portion 31 located along the corresponding diagonal axis D of the rectangular region R2 in the second surface 10b of the circuit board 10 is positioned outside the corresponding corner of the rectangular region R2 along the diagonal axis D. The stress dispersing portion 32 extends so as to have a fan-like shape or a substantially fan-like shape toward the center of the diagonal axis D with the stress receiving portion 31 being the end of the fan-like shape or substantially fan-like shape.

Therefore, compared with, for example, the other reinforcing members of the second to seventh comparative examples, the reinforcing member 30 may be reduced in size while maintaining a dispersing effect on a stress by removing unnecessary portions while maintaining a shape with which the reinforcing member 30 may function as the reinforcing member 30.

Therefore, according to the first embodiment, a size reduction of the reinforcing member 30 may be facilitated, and the pressure resistance and the long-term reliability of the electronic component-bonding portion 40 may be improved. As a result, the footprints of the passive elements 22, which are other electronic components, and the like may be secured, and the degree of freedom of mounting structures for electronic components and the degree of freedom of the wiring of the circuit board 10 increase.

In the first embodiment, the outer edge 31a of the stress receiving portion 31 located along the corresponding diagonal axis D is a side extending in the direction perpendicular to the diagonal axis D. Therefore, the outer edges 31a of the stress receiving portions 31 located along the corresponding diagonal axes D may receive with more certainty a stress concentrated at the four corners of the electronic component-bonding portion 40. As a result, the pressure resistance and the long-term reliability of the electronic component-bonding portion 40 may be further improved.

In the first embodiment, each of the stress receiving portions 31 are positioned over the area inside and the area outside the corresponding corner of the rectangular region R2 of the second surface 10b of the circuit board 10 along the corresponding diagonal axis D. Thus, the stress receiving portions 31 may receive with certainty stress concentrated at the four corners of the electronic component-bonding portion 40. Therefore, the pressure resistance and the long-term reliability of the electronic component-bonding portion 40 may be further improved.

In the first embodiment, each of the stress dispersing portions 32 is disposed at a position corresponding to the positions of at least one or more of the bonding bumps 41 on the side opposite the side on which the bonding bumps 41 are disposed. Thus, stress that has been propagated may be dispersed with certainty into the bonding bumps 41 by the stress dispersing portions 32. Therefore, the pressure resistance and the long-term reliability of the electronic component-bonding portion 40 may be further improved.

### Second Embodiment

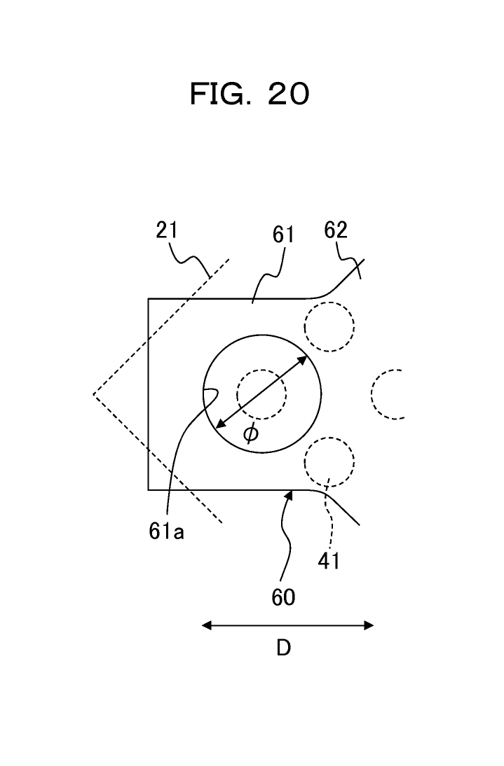

FIG. 20 is an explanatory diagram illustrating a reinforcing member 60 according to a second embodiment.

In the second embodiment, the reinforcing member 60 may have a configuration similar to that of the above-described first embodiment except for a hollow portion 61a, and thus, the detailed description of the reinforcing member 60 will be omitted. As with the reinforcing member 30 of the above-described first embodiment and the reinforcing member 50 of the above-described modification, the reinforcing member 60 of the second embodiment includes a stress receiving portion 61 and a stress dispersing portion 62.

The hollow portion 61a is formed in a portion of the stress receiving portion 61 that is in contact with the second surface 10b, and the hollow portion 61a is formed at a position corresponding to a position of the bonding bump 41 at a corresponding one of the corners of the rectangular region R2 illustrated in FIG. 2. The hollow portion 61a may be formed into any shape as long as the hollow portion 61a is positioned at the corresponding corner of the rectangular region R2 illustrated in FIG. 2. An example of the shape is a circle shape having a diameter of 1 mm or larger. The hollow portion 61a is surrounded by the stress receiving portion 61.

Here, a function of the hollow portion 61a will now be described. As illustrated in FIG. 20, the hollow portion 61a is formed with the center of the bonding bump 41 at the corner coinciding with the center of the hollow portion 61a. Although a region of a circuit board in which the reinforcing member 60 is mounted may be considered as a rigid body, the Young's modulus of a portion of the circuit board corresponding to the hollow portion 61a is lower than that of the region of the circuit board in which the reinforcing member 60 is mounted.

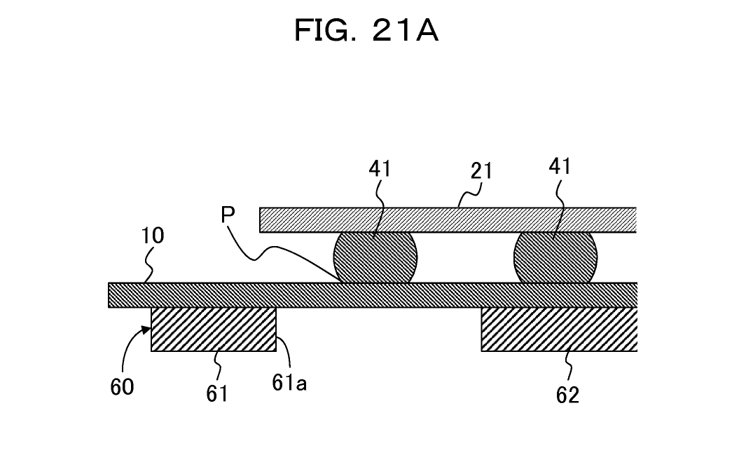

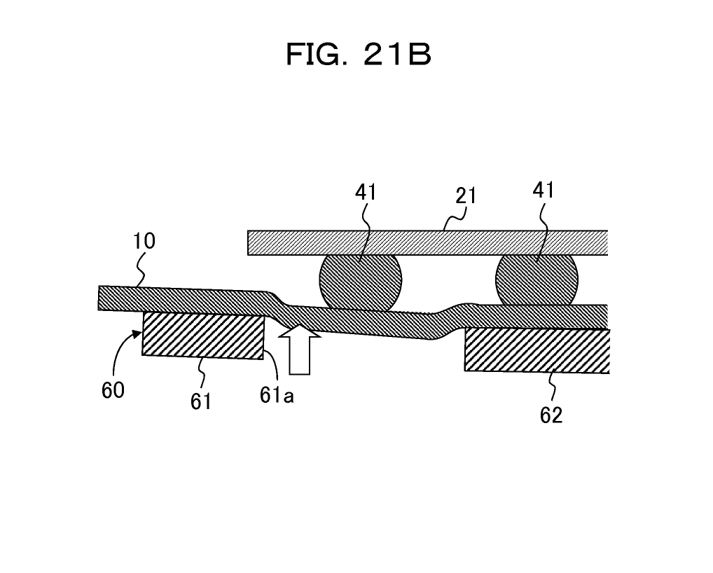

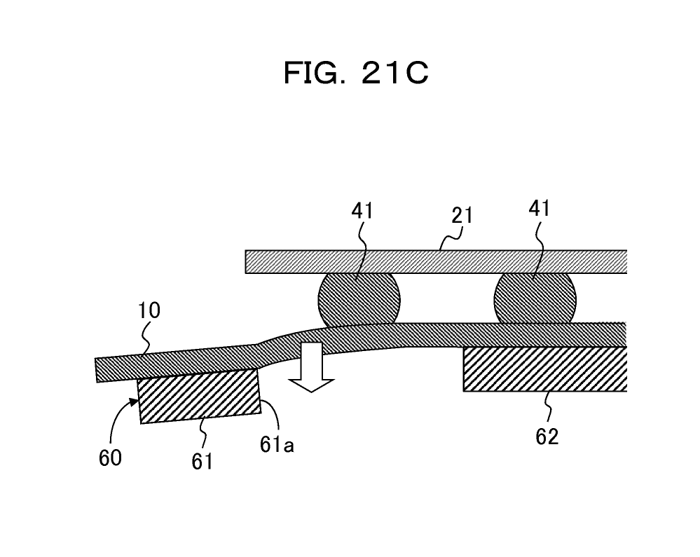

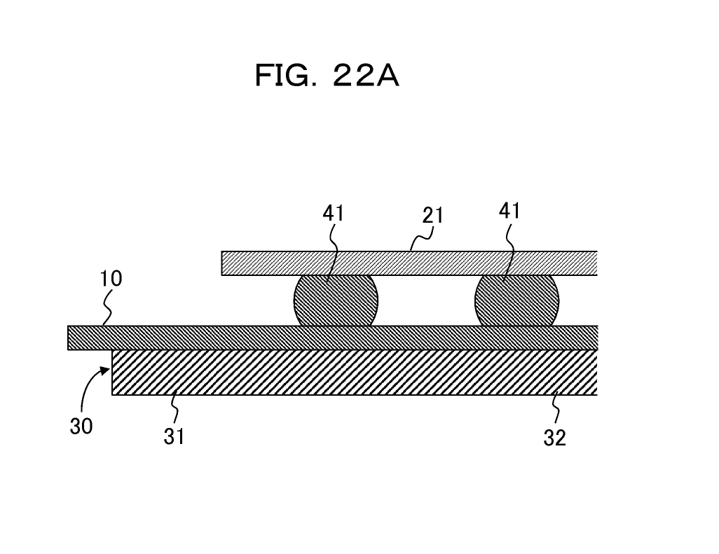

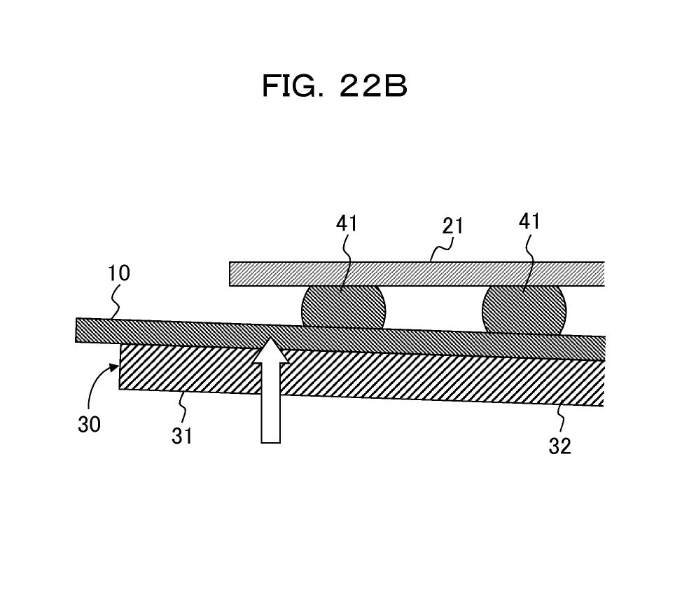

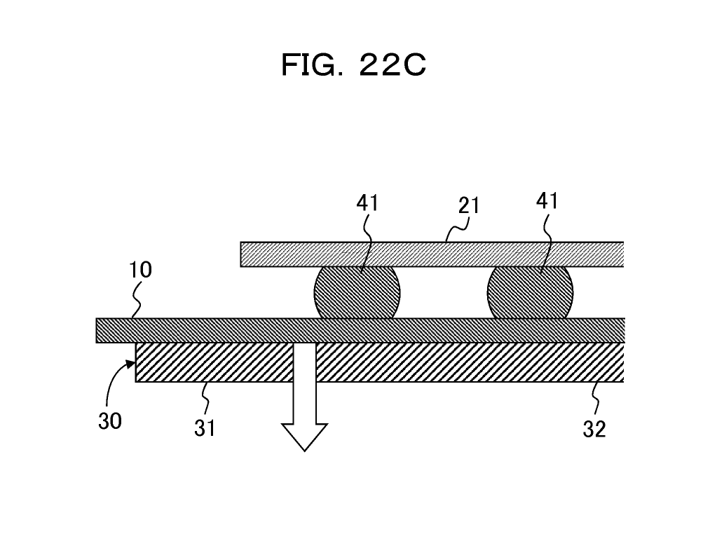

Therefore, as illustrated in FIGS. 21A to 21C, the portion of the circuit board 10 corresponding to the hollow portion 61a has a function that follows deformation. For example, as illustrated in FIGS. 21B and 22B, compared with the reinforcing member 30 of the above-described first embodiment in which a hollow portion is not formed as illustrated in FIGS. 22A to 22C, the reinforcing member 60 in which the hollow portion 61a is formed may reduce a pressure stress generated at the bonding bump 41 at the corner because the circuit board 10 deforms. Similarly, as illustrated in FIGS. 21C and 22C, the reinforcing member 60 in which the hollow portion 61a is formed may also reduce tensile stress generated at the bonding bump 41 at the corner more than the reinforcing member 60 does because the circuit board 10 deforms.

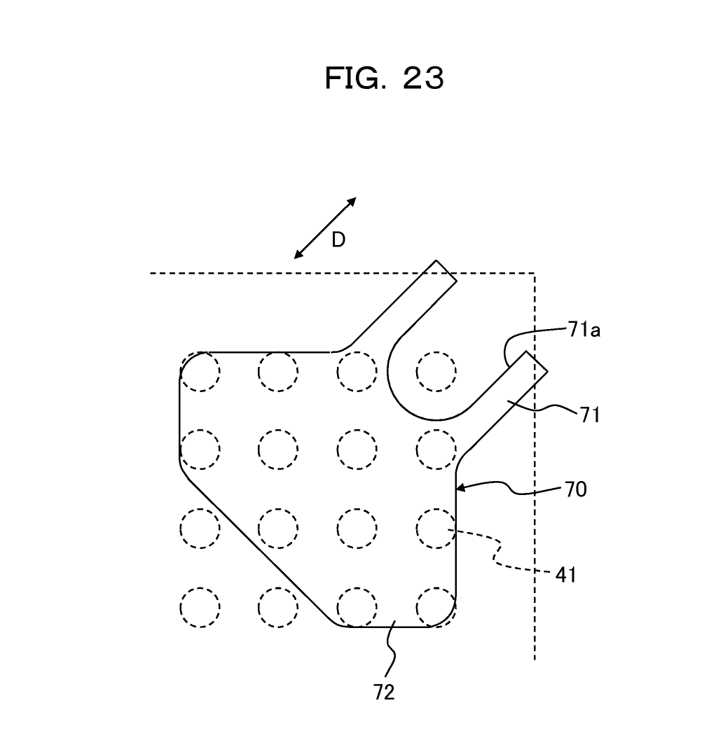

FIG. 23 is an explanatory diagram illustrating a reinforcing member 70 according to a first modification of the second embodiment.

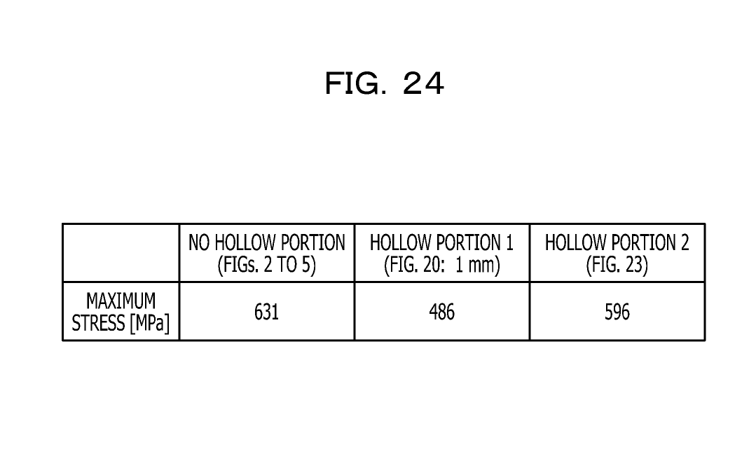

FIG. 24 illustrates simulation results indicating a maximum stress according to the second embodiment.

As illustrated in FIG. 23, a hollow portion 71a of a stress receiving portion 71 of the reinforcing member 70 is open to the outside from the stress receiving portion 71 along the diagonal axis D. As illustrated in FIG. 23, the hollow portion 71a has a shape similar to the circular portion of the hollow portion 61a of the reinforcing member 60, the shape of the hollow portion 71a extends away from the center of the diagonal axis D. However, the shape is merely an example. The reinforcing member 70 has a similar configuration to that of the reinforcing member 60 except for the hollow portion 71a.

The simulation is performed under conditions similar to those under which the simulation results illustrated in FIG. 9 are obtained in the above-described first embodiment. When the maximum stress at an outer edge of the bonding bump 41 at the corner located along the diagonal axis D illustrated in FIG. 21A that is a maximum stress point is 700 MPa or lower, a standard is satisfied.

The simulation results are as follows: when the reinforcing member 60 illustrated in FIG. 20 is used (Hollow portion 1 in FIG. 24), the maximum stress is 486 MPa, and when the reinforcing member 70 illustrated in FIG. 23 is used (Hollow portion 2 in FIG. 24), the maximum stress is 596 MPa. It is understood that the standard is satisfied in both cases, similar to when the reinforcing member 30 of the above-described first embodiment illustrated in FIGS. 2 to 5 is used (No Hollow portion in FIG. 24), where the maximum stress is 631 MPa.

Since the hollow portion 71a of the reinforcing member 70 according to the first modification of the second embodiment is open to the outside along the diagonal axis D, the hollow portion 71a of the reinforcing member 70 is easier to form than the hollow portion 61a of the reinforcing member 60.

When an underfill material is not used, considering the processes of fabricating and mounting a reinforcing member, it is desirable that the costs of the processes be equal to or lower than that of an underfill material. As a fabrication method, a method of cutting reinforcing members individually by wire cutting, laser cutting, or cutting using a milling machine is not practical and not appropriate for mass production because such a method takes time, and also the cost increase. Therefore, fabrication by press punching may be considered although precluding the use of other fabrication methods is not intended.

However, since the diameters of the hollow portions 61a and 71a are small, and the aspect ratios of the hollow portions 61a and 71a are large, it is difficult to fabricate a reinforcing member having an intended shape by punching. Therefore, a method of realizing a pseudo-hollow portion without increasing the manufacturing costs has been developed. The pseudo-hollow portion will be described in the description of a second modification.

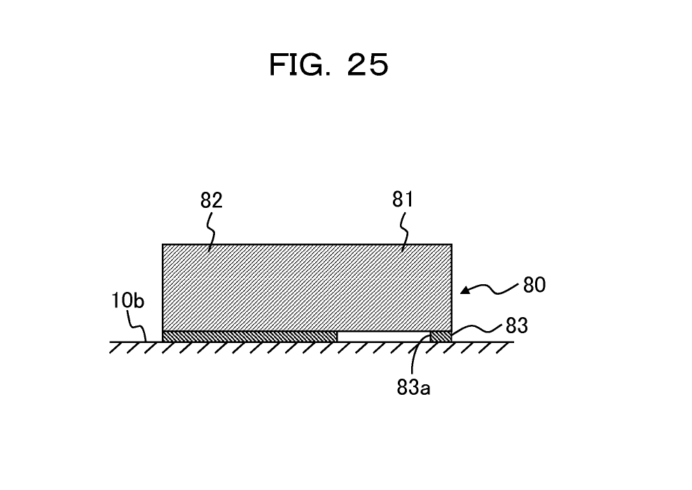

FIG. 25 is a sectional view of a reinforcing member 80 according to the second modification of the second embodiment.

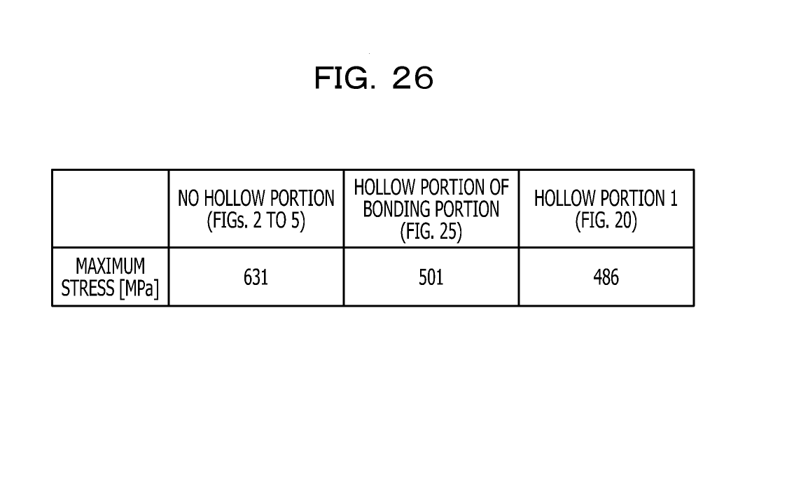

FIG. 26 illustrates simulation results indicating a maximum stress according to the second modification of the second embodiment.

The reinforcing member 80 illustrated in FIG. 25 includes, in addition to a stress receiving portion 81 and a stress dispersing portion 82, a reinforcing member-bonding portion 83 that is bonded to the second surface 10b of the circuit board 10. A hollow portion 83a is formed in the reinforcing member-bonding portion 83.

In the reinforcing member 80, the stress receiving portion 81 and the stress dispersing portion 82 are formed by punching, and a resist cover is provided on the reinforcing member-bonding portion 83 such that solder is not attached to the reinforcing member-bonding portion 83. Because of this, a portion of the reinforcing member 80 at a position corresponding to the hollow portion 83a is not in contact with the circuit board 10, and thus, an intended shape may be formed in a pseudo manner while an effect of reducing a stress is maintained.

As illustrated in FIG. 26, when the reinforcing member 80 illustrated in FIG. 25 is used (Hollow portion of Bonding Portion in FIG. 26), the maximum stress is 501 MPa. It is understood that the standard is satisfied in this case, similar to when the reinforcing member 30 of the above-described first embodiment illustrated in FIGS. 2 to 5 is used (No Hollow portion in FIG. 26), the maximum stress is 631 MPa, and when the reinforcing member 60 illustrated in FIG. 20 is used (Hollow portion 1 in FIG. 26), the maximum stress is 486 MPa. In addition, it is understood that the reinforcing member 80 may reduce the maximum stress more than the reinforcing member 30 does.

In the second embodiment, which has been described above, a configuration similar to that of the above-described first embodiment enables advantageous effects similar to those of the above-described first embodiment to be obtained, that is, the advantageous effects of facilitating a reduction in the size of the reinforcing member 60 and of improving the pressure resistance and the long-term reliability of the electronic component-bonding portion 40.

In the second embodiment, the hollow portion 61a is formed in the portion of the stress receiving portion 61, which is in contact with the second surface 10b of the circuit board 10, and the hollow portion 61a is formed at a position corresponding to the corresponding corner of the rectangular region R2. Accordingly, stress generated at the four corners of the electronic component-bonding portion 40 (the bonding bumps 41 at the four corners) may be reduced. Therefore, the pressure resistance and the long-term reliability of the electronic component-bonding portion 40 may be further improved.

In the second embodiment, the hollow portion 61a is surrounded by the stress receiving portion 61. Thus, the stress receiving portions 61 may receive with certainty stress concentrated at the four corners of the electronic component-bonding portion 40. Therefore, the pressure resistance and the long-term reliability of the electronic component-bonding portion 40 may be further improved.

In the first modification of the second embodiment, the hollow portion 71a is open to the outside from the stress receiving portion 71 along the diagonal axis D. Therefore, the hollow portion 71a may be further easily processed, and the pressure resistance and the long-term reliability of the electronic component-bonding portion 40 may be further improved.

In the second modification of the second embodiment, the hollow portion 83a is formed in the reinforcing member-bonding portion 83. Therefore, the hollow portion 83a may be still further easily processed, and the pressure resistance and the long-term reliability of the electronic component-bonding portion 40 may be further improved.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A circuit board device comprising:
a circuit board;
an electronic component bonded to a first surface of the circuit board via an electronic component-bonding portion that is disposed over a rectangular region; and
a reinforcing member disposed at one of four corners of a rectangular region of a second surface of the circuit board that is at a position corresponding to the position of the rectangular region of the first surface on a side opposite the side on which the rectangular region is present,
wherein the reinforcing member includes a stress receiving portion having an outer edge located along a diagonal axis of the rectangular region of the second surface that is positioned outside the corner of the rectangular region along the diagonal axis and a stress dispersing portion extending so as to have a fan-like shape or a substantially fan-like shape toward the center of the diagonal axis with the stress receiving portion being an end of the fan-like shape or the substantially fan-like shape.

2. The circuit board according to claim 1,
wherein a hollow portion is formed in a portion of the stress receiving portion that is in contact with the second surface, the hollow portion being formed at a position corresponding to a position of the corner of the rectangular region.

3. The circuit board according to claim 2,
wherein the hollow portion is surrounded by the stress receiving portion.

4. The circuit board according to claim 2,
wherein the hollow portion is open to the outside facing away from the stress receiving portion along the diagonal axis.

5. The circuit board according to claim 2,
wherein the reinforcing member further includes a reinforcing member-bonding portion that is bonded to the circuit board, and
the hollow portion is formed in the reinforcing member-bonding portion.

6. The circuit board according to claim 1,
wherein the outer edge of the stress receiving portion located along the diagonal axis is a side extending in a direction substantially perpendicular to the diagonal axis.

7. The circuit board according to claim 1,
wherein the stress receiving portion is disposed over an area inside and an area outside the corner of the rectangular region of the second surface along the diagonal axis.

8. The circuit board according to claim 1,
wherein the electronic component-bonding portion includes a plurality of bonding bumps that are disposed in the rectangular region of the first surface, and
the stress dispersing portion is disposed at a position corresponding to positions of at least one or more of the bonding bumps on a side opposite a side on which the bonding bumps are disposed.

9. An electronic device comprising:
a circuit board;
an electronic component bonded to a first surface of the circuit board via an electronic component-bonding portion that is disposed over a rectangular region; and
a reinforcing member disposed at one of four corners of a rectangular region of a second surface of the circuit board that is formed at a position corresponding to the position of the rectangular region of the first surface on a side opposite the side on which the rectangular region is formed,
wherein the reinforcing member includes a stress receiving portion having an outer edge located along a diagonal axis of the rectangular region of the second surface that is positioned outside the corner of the rectangular region along the diagonal axis and a stress dispersing portion extending so as to have a fan-like shape or a substantially fan-like shape toward the center of the diagonal axis with the stress receiving portion being and end of the fan-like shape or the substantially fan-like shape.
